(19) United States
(12) Patent Application Publication
(10) Pub. No.: US 2025/0112106 A1
(43) Pub. Date: Apr. 3, 2025

(54) FLEXIBLE THERMAL INTERPOSER FOR BACKSIDE COOLING OF DOUBLE-SIDED PACKAGES

(71) Applicant: Intel Corporation, Santa Clara, CA (US)

(72) Inventors: Tarek Gebrael, Chandler, AZ (US); Darshan Ravoori, Chandler, AZ (US); Matthew Magnavita, Chandler, AZ (US); Aastha Uppal, Chandler, AZ (US); Xiao Lu, Chandler, AZ (US)

(73) Assignee: Intel Corporation, Santa Clara, CA (US)

(21) Appl. No.: 18/375,337

(22) Filed: Sep. 29, 2023

(51) Int. Cl. H01L 23/367; H01L 23/498; H01L 23/538; H01L 25/00; H01L 25/10

(52) U.S. Cl. CPC H01L 23/367; H01L 23/49816; H01L 23/5384; H01L 25/105; H01L 25/50

(57) ABSTRACT

An integrated circuit (IC) device includes a device substrate with front- and backside IC dies and an integrated heat spreader over the backside die. The heat spreader and the backside die may be coupled to the backside of the device substrate within an array of contacts. The backside heat spreader may include a mask layer over a thermally conductive layer. The IC device may include or be coupled to second substrate (such as a motherboard). The backside heat spreader may be thermally coupled to a heat spreader or heat sink by vias through the second substrate. The backside heat spreader may enclose the backside IC die in an electrically conductive cage.

### BACKGROUND

The increasing demand for higher computing power and efficiency requires novel packaging architectures, including increasing package volumetric density by adding dies on a landside of the package. Integrated circuit (IC) dies added on a package landside may be chiplets for additional computing power or voltage regulators for more efficient power delivery. Adding such chips on a substrate landside introduces thermal management problems, and—given that the gap height between substrate and motherboard is on the order of hundreds of microns—incorporating a cooling solution on a package landside may be extremely challenging.

For example, thermal interface materials (TIM) added between a backside chip and motherboard can interfere with solder ball collapse and flow (i.e., proper wetting). The use of TIM may add complexity and/or cost (e.g., added cycle time) to customer, user, or manufacturer processes. Metal TIM may add still more complexities, etc. The insertion of a metallic heat slug through a motherboard to transfer the heat directly from a backside chip may cause thermo-mechanical issues, such as warpage due to the perforation of the board.

New solutions are required to advance packaging and cooling of backside IC dies and so enable increased computing powers and efficiencies.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional profile view of an integrated circuit (IC) device having a backside die on a substrate, opposite frontside dies, and a thermally conductive layer coupled to both the backside die and the backside, in accordance with some embodiments;

FIG. 2 illustrates a cross-sectional profile view of an IC device having a thermally conductive layer coupled to both a backside IC die and a substrate by a thermal interface material (TIM) and coupled to a substrate and a heat spreader by solder bumps, in accordance with some embodiments;

FIGS. 3A, 3B, 3C, 3D, and 3E illustrate cross-sectional profile views of various thermally conductive layers, mask layers, interface layers, and combinations thereof, in accordance with some embodiments;

FIGS. 4A, 4B, 4C, and 4D illustrate cross-sectional profile and plan views of devices with heat-spreading layers coupled to a substrate at interfaces on two sides and all sides of a backside IC die, in accordance with some embodiments;

FIG. 5 is a flow chart of methods for forming an IC system having an integrated heat spreader (IHS) over a backside IC die, including coupling a thermally conductive layer to a package substrate and an IC die, in accordance with some embodiments;

FIGS. 6A, 6B, 6C, 6D, 6E, and 6F illustrate cross-sectional profile views of an IC device with a thermally conductive layer over a backside IC die and coupled to substrates, at various stages of manufacture, in accordance with some embodiments;

FIG. 7 illustrates a diagram of an example data server machine employing an IC device having an IHS between a package substrate and motherboard and over a backside die, in accordance with some embodiments; and

FIG. 8 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with backside dies, for example, IC dies coupled to a package substrate between the package substrate and a motherboard.

An ultra-thin and flexible cooling solution may be added to IC packages with backside dies (or chips). The solution may act as a heat spreader and interposer: it spreads thermal energy from the heat-generating die to a larger area of the package substrate, and it transfers this heat from the chip to the motherboard, enhancing the thermal performance. The heat spreader has a thermally conductive core layer (e.g., of copper, graphite, diamond, or other thermally conductive material) and may also have an optional mask layer over the core layer, for example, to localize solder bumps for coupling the core layer to the motherboard. An interface layer or layers may be used over a core layer that does not bond sufficiently well with solder. Composite, organic, and/or thin-metal layers may be used to provide mechanical flexibility.

A thin and flexible thermal dissipation solution may enable adding chips (or more powerful chips) to package backsides, which may bring chips closer together and so improve performance. Improved thermal dissipation may reduce or eliminate hotspots, which may improve electrical performance, including minimizing package reliability issues. Reliability issues are also reduced by the use of flexible layers and less resultant mechanical stress (for example, due to differing thermal expansion). The flexibility and small form factor also provide compatibility for the disclosed solution with existing packaging schemes.

The heat spreader may be integrated with the IC package early enough in a fabrication flow to minimize or even eliminate impact to downstream customers or manufacturers. Die metallization is not required. Manufacturers may use their conventional solder application processes and need not add thermal interface materials (TIM) to the packages or their processes. All TIM application may be performed at early processing stages, prior to downstream fabrication.

Electrically conductive or insulating core layers may be used. Electrically conductive core layers may advantageously provide shielding from electromagnetic interference (EMI).

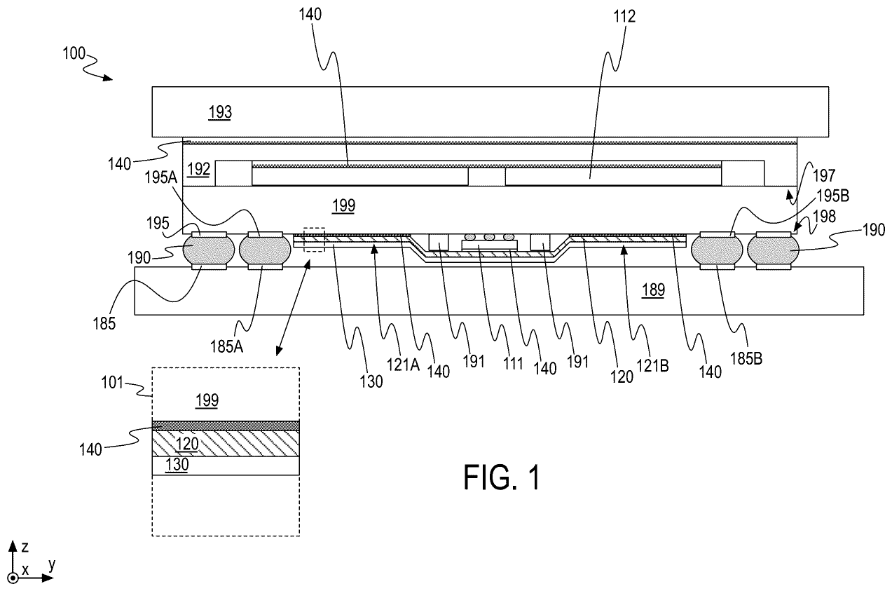

FIG. 1 illustrates a cross-sectional profile view of an IC device 100 having a backside die 111 on a substrate 199, opposite frontside dies 112, and a thermally conductive layer 120 coupled to both backside die 111 and the backside 198, in accordance with some embodiments. Thermally conductive layer 120 is coupled to backside 198 (at least) on both sides of backside die 111. Dies 111, 112 may be IC dies, which is a term used here to include chiplets and other chips or dies that may be functional circuit blocks, e.g., designed to be combined with other dies, for example, on interposers or other substrates.

IC device 100 includes substrate 199, IC dies 111, 112, and thermally conductive layer 120. Substrate 199 may be a package substrate, interposer, or other substrate, e.g., having multiple layers of insulating material (e.g., dielectric material) and layers of electrical interconnects (such as metallization lines or wires) within the insulating material. Different layers of electrical interconnects may be coupled by vertical interconnects (such as metal vias). Substrate 199 may include organic and/or inorganic materials.

Substrate 199 has a frontside 197 and an opposing backside 198. One or more IC dies 112 are on and coupled to frontside 197. IC die 111 is on and coupled to backside 198. Substrate 199 is between dies 111, 112. Substrate 199 includes multiple interconnect interfaces 195 on backside 198. IC die 111 is coupled to substrate 199 on backside 198 between interconnect interfaces 195 (e.g., between interconnect interfaces 195A, 195B).

In some embodiments, device 100 includes (or is coupled to) substrate 189, which may be a printed circuit board (PCB), such as a motherboard. Substrate 189 may have multiple layers of electrical lines or wires within insulating material, for example, interconnected by vias. Substrate 189 may include organic and/or inorganic materials. Substrate 199 is coupled to substrate 189. Substrate 189 includes multiple interconnect interfaces 185, which are coupled to interconnect interfaces 195 of substrate 199. In the example of FIG. 1, interconnect interfaces 185, 195 (and so substrates 189, 199) are coupled by solder bumps 190 between interfaces 185, 195. Thermally conductive layer 120 and IC die 111 are on backside 198 of substrate 199 and are between substrates 189, 199. Thermally conductive layer 120 and IC die 111 (both on backside 198 of substrate 199) are between interconnect interfaces 185A, 185B (on substrate 189).

Interconnect interfaces 185, 195 enable mechanical coupling, e.g., bonding, of substrates 189, 199. Interconnect interfaces 185, 195 also enable electrical coupling of substrates 189, 199. For example, interfaces 185, 195 may interconnect electrical circuits in IC dies 111, 112 to components, power supplies, etc., on or coupled to substrate 189. Interconnect interfaces 185, 195 may be contacts, lands, bond pads, solder pads, etc., e.g., of metal, for coupling substrates 189, 199. In some embodiments, a bonding material is used to bond interconnect interfaces 185, 195. In at least some such embodiments, such a bonding material is electrically conductive (for example, solder bumps 190). In some embodiments, components, circuits, etc., in IC dies 111, 112 are electrically coupled through substrate 189 to a power supply (not shown) coupled to substrate 189. In some such embodiments, device 100 includes the power supply.

IC dies 111, 112 may be coupled to substrate 199 by any suitable means. In the example of FIG. 1, die 111 is coupled by solder bumps to substrate 199. In some embodiments, one or more of dies 111, 112 are coupled to substrate 199 by other means, e.g., direct bonds, including hybrid bonds.

IC dies 111, 112 may be any type of dies, e.g., memory chips, etc. In some embodiments, dies 111, 112 are processors, voltage regulators, etc., that consume relatively high amounts of electrical power and consequently generate appreciable amounts of thermal energy (e.g., heat). Frontside dies 112 may be more conveniently cooled by means on frontside 197, where there is more room for structures, such as integrated heat spreader (IHS) 192 and heat sink 193. IHS 192 is coupled to IC dies 112, e.g., by a thermal interface material (TIM) 140. IHS 192 may also be coupled to substrate 199 by TIM 140 (or by other means). IHS 192 is also coupled to heat sink 193, e.g., by TIM 140. Heat generated at dies 112 may be readily conducted, for example, through one or more TIM 140, to IHS 192 and heat sink 193. IHS 192 may have a larger area than dies 112 and help dissipate to heat sink 193. IHS 192 and heat sink 193 may be any suitable structures and of any suitable material(s). IHS 192 may be of or include material(s) with high thermal conductivity. In many embodiments, IHS 192 is or includes a continuous layer of copper. IHS 192 may be of or include composites with these and/or other materials. Heat sink 193 be of similar materials and may be cooled (actively or passively) by a fluid, such as air or a liquid.

Heat generated at die 111 may not readily dissipate through IHS 192 and heat sink 193 (e.g., through substrate 199 and heat-generating die(s) 112). For example, substrate 199 may not be sufficiently thermally conductive. If thermally conductive, substrate 199 may be overly thick. Also, any thermal conduction path upward to frontside 197, IHS 192, and heat sink 193 for heat generated at IC die 111 may be through dies 112, whose own heat may inhibit the dissipation of heat from die 111 upward.

Thermally conductive layer 120 is an IHS coupled to backside 198 and IC die 111. Layer 120 may help dissipate heat from die 111 at least laterally along substrate 199, e.g., on backside 198, away from die 111. Thermally conductive layer 120 is a layer of (or including) any sufficiently thermally conductive material. Thermally conductive layer 120 may be or include one or more composite materials. Thermally conductive layer 120 may advantageously be a flexible layer 120, which (relative to rigid assemblies) may minimize induced mechanical stresses, for example, between adjacent structures thermally expanding at different rates. Minimizing such thermo-mechanical stresses in turn reduces, e.g., package reliability risks.

In some embodiments, layer 120 is (or includes) a layer of copper, e.g., a continuous copper foil layer. Advantageously, copper is thermally conductive (e.g., having a thermal conductivity of ˜400 W/m·K (i.e., W·m⁻¹·K⁻¹, watts per meter-kelvin)) and flexible, if desired. A copper layer 120 may beneficially be made, for example, more or less thick to suit a particular application. In some embodiments, a copper layer 120 has a thickness of 200 μm or more, which may provide more thermal conductance, e.g., for dissipating heat away from IC die 111. In some embodiments, a copper layer 120 has a thickness of 50 μm or less, which may provide sufficient thermal conductance and improved flexibility, e.g., less stiffness, for minimizing mechanical stresses. In some embodiments, a copper layer 120 has a thickness of approximately 100 μm, which may provide an optimal balance (e.g., for those embodiments) of various properties or qualities, such as flexibility, thermal conductance, etc. In some embodiments, a copper layer 120 has advantageous characteristics due to its electrical conductivity.

In some embodiments, layer 120 is or includes a layer of graphite. A graphite layer 120 may have a very high thermal conductance, e.g., anisotropically. For example, highly ordered pyrolytic graphite may have a thermal conductivity of ˜400 W/m·K in the ab directions (e.g., laterally, parallel to the atomic plane), which may be used to beneficially dissipate heat away from IC die 111, along backside 198 and substrate 199. Graphite fiber (e.g., mesophase, pitch-based carbon fiber) may have a thermal conductivity of >1000 W/m·K along the fiber. Graphite may be deployed in a composite layer 120 to utilize the high (but anisotropic) thermal conductivity while minimizing disadvantages of the graphite.

In some embodiments, layer 120 is or includes a layer of a composite material. In some such embodiments, the composite includes diamond. Diamond has a thermal conductivity of 1000 W/m·K or more (for example, depending on purity), which may be advantageous in a composite layer 120. A composite layer 120 including diamond (or other composite layers 120) may use a polymer matrix (such as a TIM), but with an added diamond (or other material) fill. Other (e.g., ceramic) materials may be sufficiently thermally conductive to be deployed as a fill material in such a composite.

Other thermally conductive materials, in the alternative or in addition to those described, may be deployed in layer 120. In many embodiments, a thermally conductive material, e.g., in layer 120, has a thermal conductivity of at least 200 W/m·K. In some such embodiments, a thermally conductive material has a thermal conductivity of 250 W/m·K (or greater), for example, where a thinner (e.g., less stiff) layer 120 is required. In some such embodiments, a thermally conductive material has a thermal conductivity of 300 W/m·K or more, for example, where a yet thinner layer 120 is required, e.g., to fit between substrates 189, 199.

Thermally conductive layer 120 is coupled by a TIM 140 to substrate 199. Thermally conductive layer 120 is coupled by TIM 140 to IC die 111. Die 111 is between layer 120 and substrate 199. Thermally conductive layer 120 is coupled by TIM 140 to backside 198 on both sides of IC die 111 (e.g., between die 111 and interconnect interface 195A and between die 111 and interconnect interface 195B). For example, layer 120 has a first end 121A and a second end 121B opposite end 121A, and layer 120 is coupled to substrate 199 at both ends 121A, 121B. (End 121A is between die 111 and interconnect interface 195A, and end 121B is between die 111 and interconnect interface 195B.) IC die 111 is coupled to substrate between ends 121A, 121B.

The TIM 140 between thermally conductive layer 120 and one or both of die 111 and substrate 199 may be the same or a different TIM 140 as between IHS 192 and heat sink 193 or between IHS 192 and IC dies 112. TIM 140 may be any suitable material. For example, TIM 140 may advantageously be very thermally conductive. TIM 140 may advantageously be tacky or otherwise capable of coupling adjacent or abutting structures (e.g., layer 120 to die 111 and substrate 199). In many embodiments, TIM 140 is or includes a polymer, for example, in a thermal paste, thermal adhesive, thermal gap filler, etc. In some embodiments, TIM 140 is a metal TIM. Other materials may be employed.

Device 100 may include a covering layer 130, for example, of an insulating and/or organic material, over heat-spreading or core layer 120. Thermally conductive layer 120 is between layer 130 and substrate 199, and layer 130 covers a region of layer 120. In some embodiments, layer 130 is of (or includes) an organic material. In some such embodiments, organic layer 130 includes one or more polymers. In some such embodiments, layer 130 is a polyimide layer 130. Such materials may have suitable properties (e.g., heat tolerance, patternability, etc.). In some embodiments, layer 130 is an electrically insulating layer 130. Layer 130 may electrically insulate core layer 120, e.g., from substrate 189. In many embodiments, layer 130 covers (and is coupled with and to) layer 120 in such a manner that layers 120, 130 are parts of an integrated structure, e.g., an IHS.

Expanded view 101 shows layers 120, 130 coupled to substrate 199 by TIM 140. Thermally conductive layer 120 is between layer 130 and substrate 199. Covering or mask layer 130 is between thermally conductive layer 120 and substrate 189, and layer 130 may electrically insulate layer 120 from adjacent structures, such as substrate 189. FIG. 1 (including expanded view 101) is not necessarily to scale. In some embodiments, layers 120, 130 have substantially equal thicknesses. In other embodiments, layer 120 is two or more times thicker than layer 130.

Thermally conductive layer 120 is over IC die 111 on backside 198. In some embodiments, layer 120 is also over one or more backside components 191 adjacent die 111. In some such embodiments, layer 120 is coupled to the one or more backside components 191 and dissipates heat away from components 191, for example, laterally outward to backside 198 adjacent ends 121.

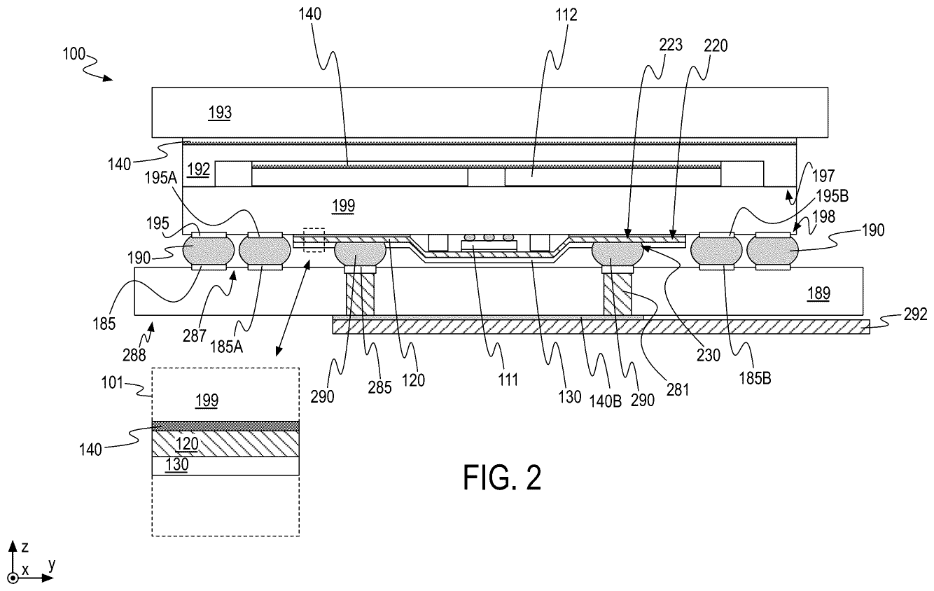

FIG. 2 illustrates a cross-sectional profile view of IC device 100 having thermally conductive layer 120 coupled to both backside IC die 111 and substrate 199 by TIM 140 and coupled to substrate 189 and a heat spreader 292 by solder bumps 290, in accordance with some embodiments. The example of FIG. 2 is much as described at FIG. 1, for example, with thermally conductive layer 120 coupled to die 111 and substrate 199 on backside 198. Notably, mask layer 130 has a group of openings 230 in and through layer 130, and thermally conductive layer 120 contacts solder bumps 290 through openings 230. Thermally conductive layer 120 is a thermal interposer coupled to substrate 189 by solder bumps 290 and to heat spreader 292 by solder bumps 290, thermal vias 281, and TIM 140.

As described at FIG. 1, substrates 189, 199 and interconnect interfaces 185, 195 are coupled by solder bumps 190 on interfaces 185, 195. In the example of FIG. 2, multiple thermal solder bumps 290 are on thermally conductive layer 120, and layer 120 and substrate 189 are coupled by solder bumps 290. Substrate 189 provides another potential heat dissipation path for heat generated at IC die 111. Substrate 189 includes one or more thermal vias 281 through substrate 189. Thermal vias 281 extend from interconnect interfaces 285 on a side 287 of substrate 189 to a side 288. Vias 281 are coupled to thermally conductive layer 120 by solder bumps 290 and interconnect interfaces 285. Vias 281 are coupled by (the same or a different) TIM 140 to heat spreader 292 on side 288 of substrate 189 opposite substrate 199.

Heat dissipated from IC die 111 to heat spreader 292 may be further dissipated and readily conducted on to a heat sink coupled to heat spreader 292. Heat spreader 292 may be any suitable structure and may be of any suitable material(s). Heat spreader 292 may include material(s) with high thermal conductivity. In many embodiments, heat spreader 292 is a metallization structure. In some such embodiments, heat spreader 292 is or includes copper.

Thermal solder bumps 290 may be the same as or similar to solder bumps 190, which may conduct current and/or otherwise electrically couple interfaces 185, 195. Like solder bumps 190, solder bumps 290 may conduct both thermal and electrical energy. In some embodiments, solder bumps 290 are smaller and have a shorter bump-to-bump pitch between bumps 290 (e.g., relative to bumps 190). Solder bumps 290 contact interconnect interfaces 285 on side 287. Interfaces 185 and 285 on side 287 of substrate 189 may be the same as or similar to, e.g., contacts capable of conducting either or both of thermal and electrical energy.

Thermal vias 281 may be the same as or similar to other vias in substrates 189, 199, which may conduct current and/or otherwise electrically couple (e.g., between and through) layers of substrates 189, 199. Vias 281 include a thermally conductive material, such as a metal. In many embodiments, vias 281 are hollow or filled copper structures. For example, copper vias 281 may be solid copper or tubes of copper, which may (or may not) be filled with a thermally conductive material.

Thermally conductive layer 120 is between mask layer 130 and substrate 199. Mask layer 130 is between layer 120 and substrate 189. Layer 120 has a covered region 220, covered by mask layer 130. Each of openings 230 in and through mask layer 130 corresponds to an uncovered (by mask layer 130) sector 223 of layer 120. Solder bumps 290 contact thermally conductive layer 120 through openings 230 in and through mask layer 130. Solder bumps 290 are in and contact uncovered sectors 223, each sector 223 adjacent and encircled or surrounded by region 220 and adjacent to a corresponding opening 230.

Expanded view 101 shows layers 120, 130 coupled to substrate 199 by TIM 140. Layers 120, 130 may be substantially as described elsewhere herein (for example, at least at FIG. 1). Mask layer 130 and openings 230 (not shown in view 101) may provide bounds for containing or delimiting solder bumps 290. Thermally conductive layer 120 may be a metal (such as copper) on which solder may (too) easily wet or flow. Without a mask to contain solder bumps 290, solder may spread, e.g., over a metal layer 120, and insufficient solder may remain placed at desired locations. In some embodiments, thermally conductive layer 120 is or includes a material (e.g., a non-metallic material) that does not readily form a bond with solder. In some such embodiments, an interface layer is between layers 120, 130, as is described elsewhere herein.

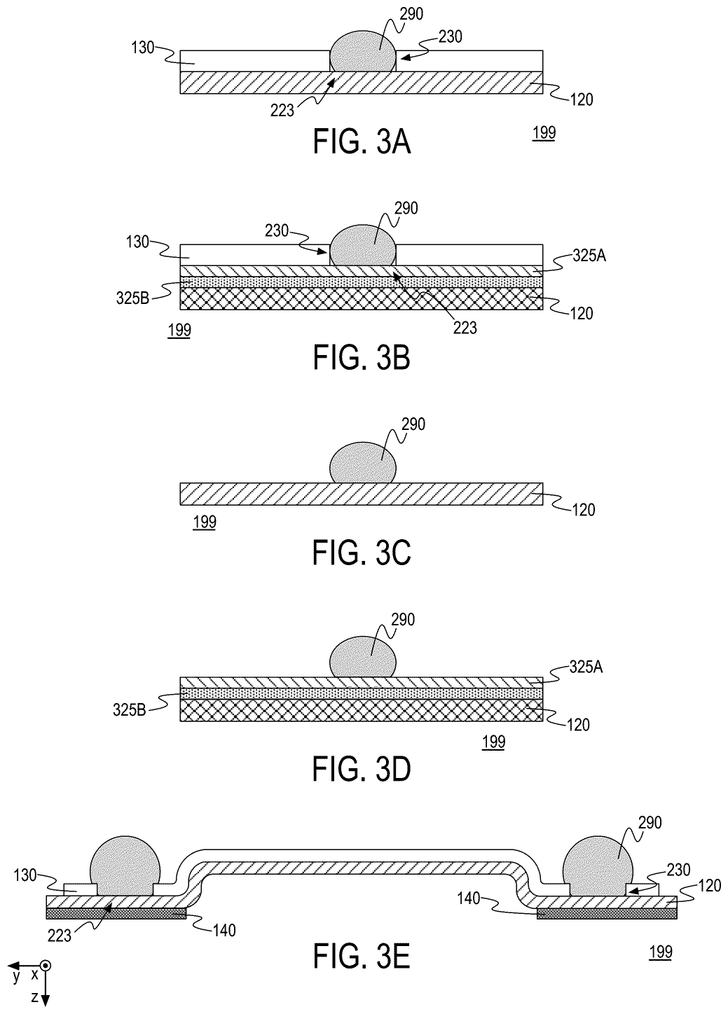

FIGS. 3A, 3B, 3C, 3D, and 3E illustrate cross-sectional profile views of various thermally conductive layers 120, mask layers 130, interface layers 325, and combinations thereof, in accordance with some embodiments. FIG. 3A shows thermally conductive layer 120 and mask layer 130 much as previously described (e.g., at least at FIG. 2). Layer 120 may be a metal layer 120 (for example, a copper layer 120) with which solder of bumps 290 readily bonds. Mask layer 130 covers layer 120, but with opening 230 leaving uncovered sector 223 of layer 120. Solder bump 290 is on layer 120 at sector 223 in (and corresponding to) opening 230. Mask layer 130 may be an organic layer 130, e.g., of polyimide or other polymer(s). Mask layer 130 may be a conventional solder resist or solder mask. Mask layer 130 may utilize other materials. Core layer 120 is between layer 130 and substrate 199. Core layer 120 may have other sectors 223 in other openings 230 in layer 130, and other solder bumps 290 may be in openings 230 for bonding to other structures (e.g., thermal vias), as shown at least at FIG. 2.

FIG. 3B illustrates thermally conductive layer 120 of a material (e.g., a non-metallic material) that does not readily form a bond with solder. Interface layers 325 are between layers 120, 130 and may facilitate coupling thermally conductive layer 120, e.g., to a thermal via through solder bump 290. For example, interface layer 325A may form a bond with solder (of bumps 290). Interface layer 325A may be deposited on interface layer 325B. Interface layer 325B may be deposited on core layer 120. Interface layer(s) 325 may be part of an IHS with layers 120, 130. Interface layers 325A, 325B may link core, thermally conductive layer 120 to solder bump 290 (and other structures through bump 290). Interface layers 325 may be of any suitable material(s). In some embodiments, thermally conductive layer 120 is a composite layer 120 including graphite. In some such embodiments, device 100 has interface layers 325, including a titanium adhesion layer 325A on graphite layer 120, and a gold layer 325B (e.g., to solder bump 290 to) on titanium layer 325A. Although FIG. 3B shows two interface layers 325, in some embodiments, other amounts of layers 325 are employed. In some embodiments, a single interface layer 325 is between layers 120, 130. A single interface layer 325 may satisfactorily interface between some thermally conductive layers 120 and solder bump 290 (or mask layer 130). In some embodiments, device 100 has more than two interface layers 325 between layers 120, 130, for example, three or more interface layers 325. Additional interface layers 325 may provide additional flexibility (e.g., in materials choices). Fewer interface layers 325 (or at least a lower total thickness of layers 325) may be beneficial, for example, to reduce thermal resistance between thermally conductive layer 120 and another heat spreader or heat sink. Other materials may be deployed.

Thermally conductive layer 120 is between interface layer(s) 325 and substrate 199. Interface layers 325 are between mask layer 130 and substrate 199. Mask layer 130 confines solder bump 290 to a desired placed position. Mask layer 130 covers a region 220, but of interface layer 325B, and bump 290 is in opening 230 on layer 325B. Solder bumps 290 may couple layers 325 to other structures (e.g., thermal vias), and core layer 120 may be coupled to other structures through layers 325.

FIGS. 3C and 3D shows thermally conductive layer 120 much as described at FIGS. 3A and 3B, both with and without interface layer(s) 325, but without optional mask layer 130. In some embodiments, mask layer 130 is not necessary.

FIG. 3E illustrates an example deployment of a thin copper layer 120, e.g., a flexible foil layer 120, as may be over an IC die and adjacent components on substrate 199. Mask layer 130 has openings 230. Solder bumps 290 are on core copper layer 120 at sectors 223 in corresponding openings 230. Core layer 120 is coupled to substrate 199 by TIM 140.

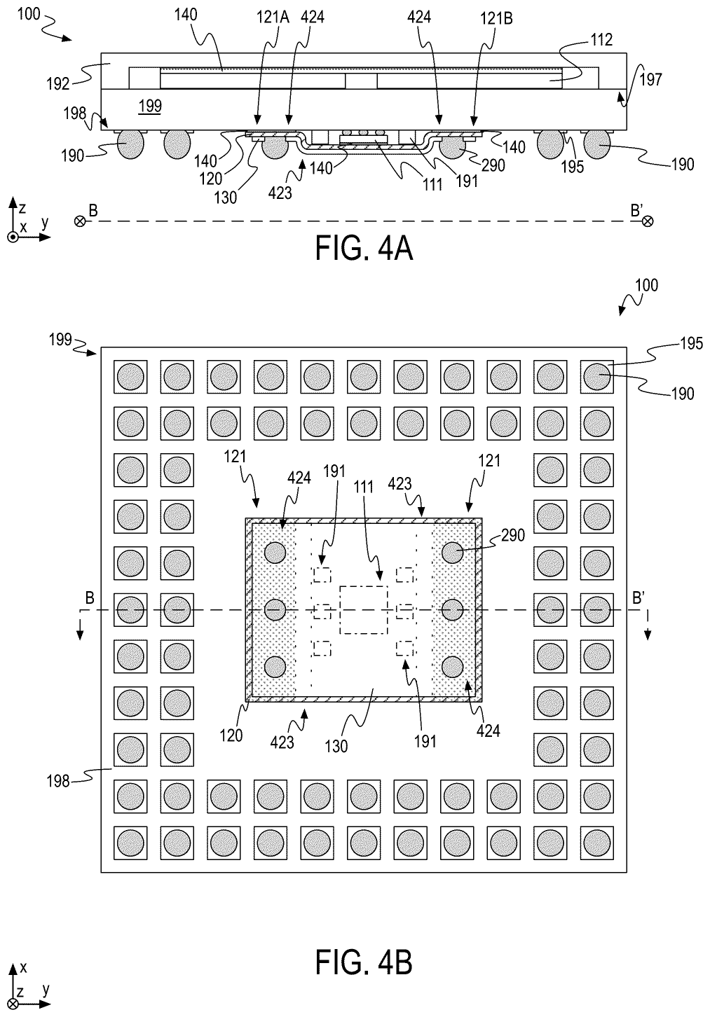

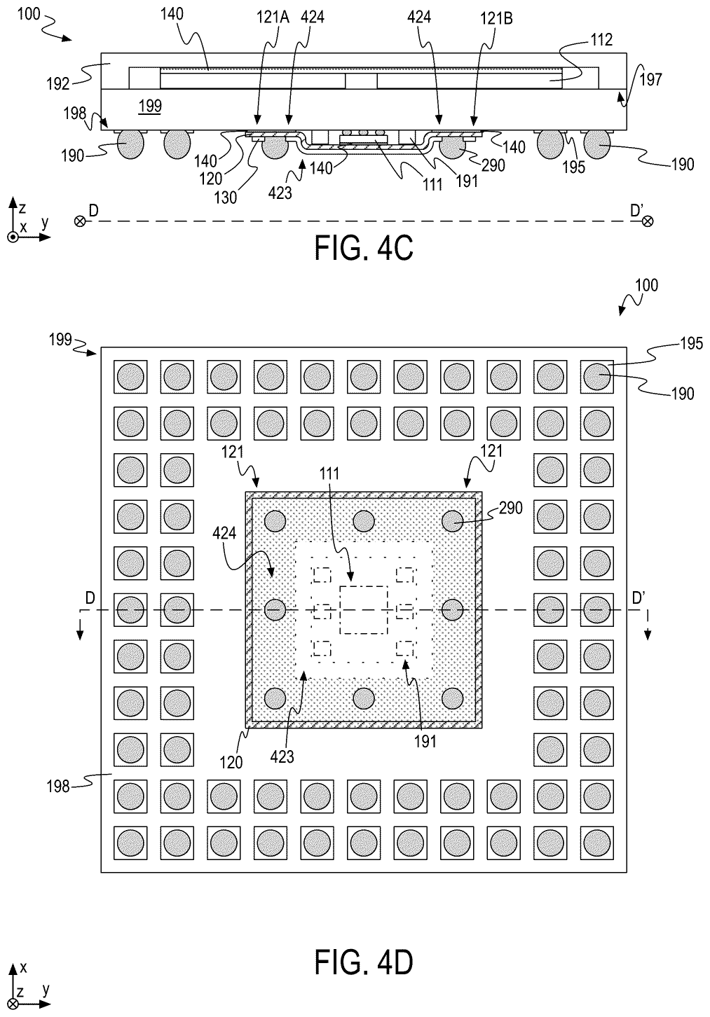

FIGS. 4A, 4B, 4C, and 4D illustrate cross-sectional profile and plan views of devices 100 with heat-spreading layers 120 coupled to substrate 199 at interfaces 424 on two sides and all sides of backside IC die 111, in accordance with some embodiments. FIGS. 4A and 4B show a device 100 much as described previously herein (e.g., at FIG. 2). The profile view of FIG. 4A, taken at cross-sectional line B-B′, is shown for reference. Core layer 120 is a strip, for example, of a flexible copper foil, coupled to substrate 199 by TIM 140 at interface 424 between (backside 198 of) substrate 199 and ends 121 of layer 120. Layer 120 has first end 121A and second end 121B opposite end 121A. Layer 120 is coupled to substrate 199 at both ends 121A, 121B by TIM 140. The profile view of FIG. 4A shows the transitions 423 of layer 120 from ends 121 coupled to substrate 199, up off of substrate 199 and over IC die 111 (and components 191) between ends 121. Interface 424 is to both sides of IC die 111, but the sides between ends 121 (e.g., in both x-directions from die 111) may be open. Heat may be readily dissipated to either side from die 111 through thermally conductive layer 120 to substrate 199 at ends 121. Solder bumps 290 are over interface 424 (of TIM 140 between substrate 199 and core layer 120), which may facilitate further heat dissipation (for example, to another substrate, such as a motherboard, with (e.g., thermal) vias).

FIG. 4B illustrates a plan view of landside or backside 198 of substrate, including solder bumps 190 on interconnect interfaces 195 and solder bumps 290 over layers 120, 130 (e.g., on layer 120, in openings 230 through layer 130). Solder bumps 290 are to both sides of die 111, towards ends 121. Solder bumps 290 are over interface 424, which is behind or under layers 120, 130, so is shown as stippled. Transitions 423 are between interface 424 and IC die 111 and components 191. IC die 111 and components 191 are between transitions 423.

FIGS. 4C and 4D illustrate show a device 100 much as described previously herein (e.g., at FIGS. 4A and 4B). Notably, in the example of FIGS. 4C and 4D, interface 424 encircles IC die 111 on backside 198. Together, core layer 120 and substrate 199 enclose die 111. The profile view of FIG. 4C, taken at cross-sectional line D-D′, is shown as a useful reference, aligned with the plan view of FIG. 4D. Core layer 120 is a flexible copper foil, coupled to substrate 199 by TIM 140 at interface 424 on backside 198 between IC die 111 and interconnect interfaces 195. The profile view of FIG. 4C shows some of transition 423 of layer 120 from on substrate 199, up off of substrate 199 and over IC die 111 (and components 191). Interface 424 is to the sides of IC die 111. Heat may be readily dissipated from die 111 through thermally conductive layer 120 to substrate 199. Solder bumps 290 are over interface 424 (of TIM 140 between substrate 199 and core layer 120), which may facilitate further heat dissipation (for example, to another substrate, such as a motherboard, with (e.g., thermal) vias).

FIG. 4D illustrates a plan view of landside or backside 198 of substrate, including solder bumps 190 on interconnect interfaces 195 and solder bumps 290 over layers 120, 130 (e.g., on layer 120, in openings 230 through layer 130). Solder bumps 290 are to all sides of die 111, in both the x- and y-directions. Solder bumps 290 are over interface 424, which is shown as stippled, behind or under layers 120, 130. Interface 424 encircles IC die 111 on backside 198, and core layer 120 and substrate 199 enclose die 111. Transitions 423 are on all sides, between interface 424 and IC die 111 and components 191. IC die 111 and components 191 are between transitions 423 on all sides. Electrically conductive core layers 120 (such as copper) may have advantages over layers 120 of electrically insulating materials. In addition to thermal management benefits, electrically conductive core layer 120 may provide die 111 with EMI shielding. Heat-spreader layer 120 may form an EMI cage around IC die 111 (and other components, e.g., components 191) with substrate 199. EMI shielding, including an EMI cage, may improve device signal integrity.

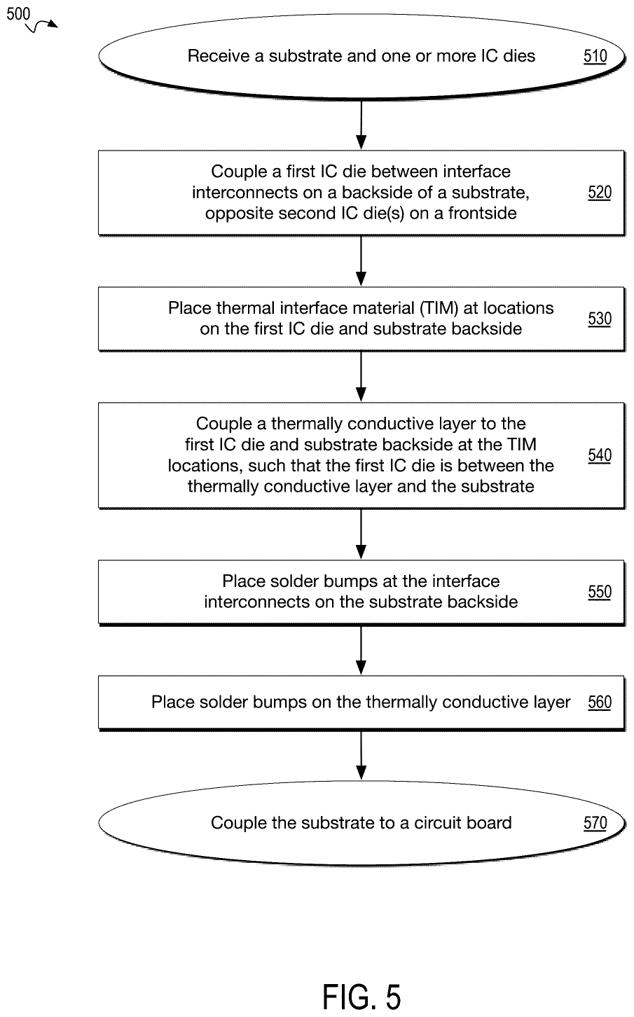

FIG. 5 is a flow chart of methods 500 for forming an IC system having an IHS over a backside IC die, including coupling a thermally conductive layer to a package substrate and an IC die, in accordance with some embodiments. Methods 500 include operations 510-570. Some operations shown in FIG. 5 are optional. Additional operations may be included. FIG. 5 shows an example sequence, but the operations can be done in other orders as well, and some operations may be omitted. Some operations can also be performed multiple times before other operations are performed. For example, TIM may be placed at multiple locations. Some operations may be included within other operations so that the number of operations illustrated FIG. 5 is not a limitation of the methods 500.

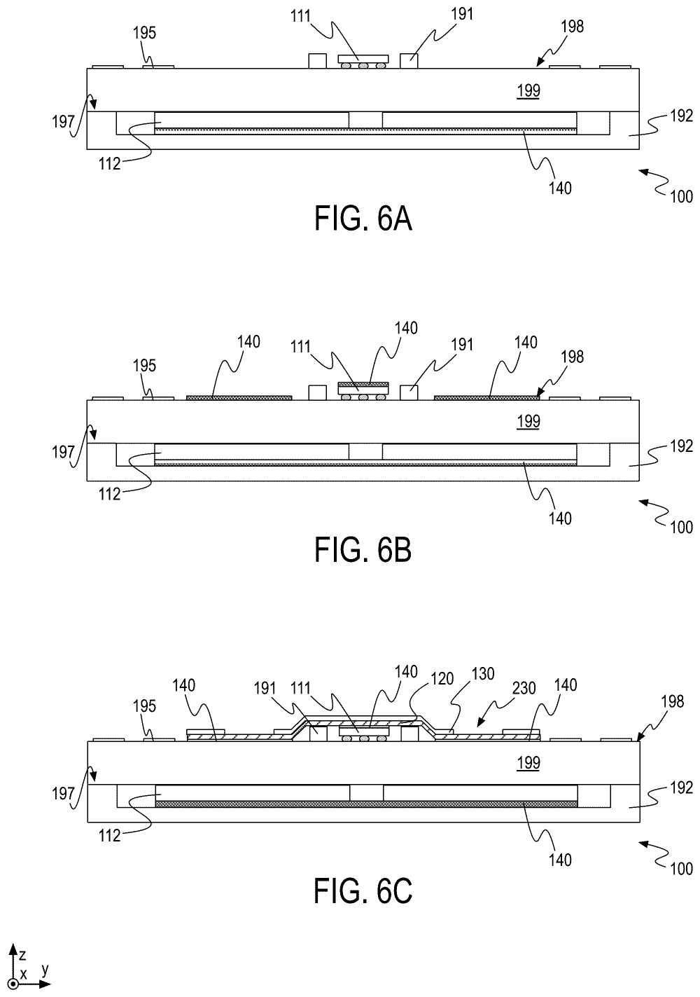

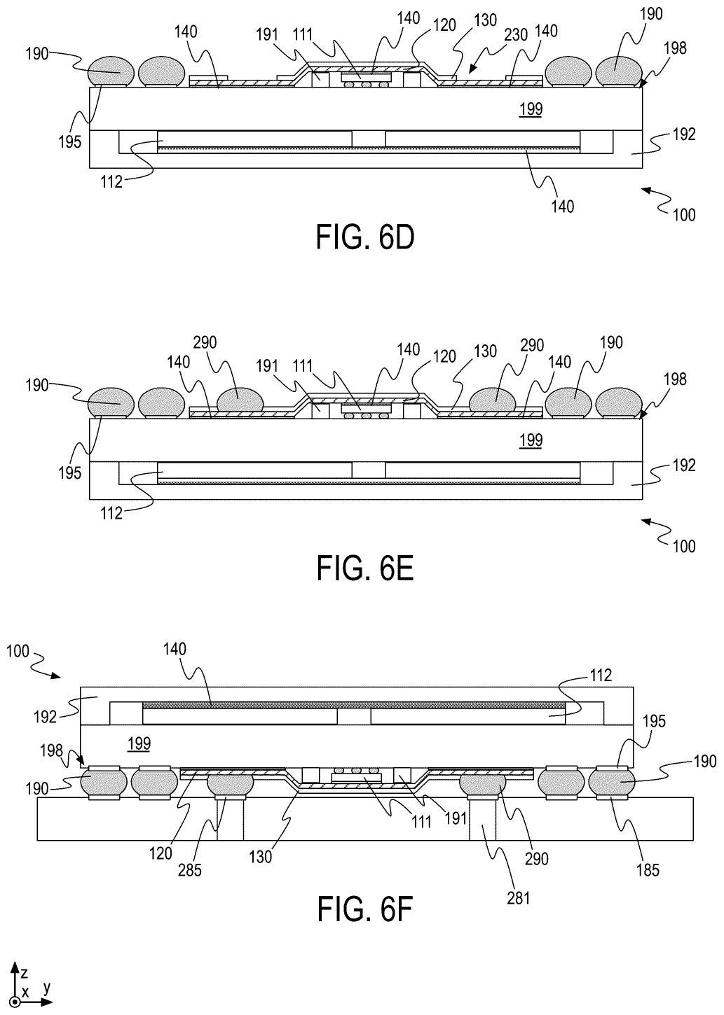

FIGS. 6A, 6B, 6C, 6D, 6E, and 6F illustrate cross-sectional profile views of an IC device 100 with thermally conductive layer 120 over backside IC die 111 and coupled to substrates 189, 199, at various stages of manufacture, in accordance with some embodiments.

Returning to FIG. 5, methods 500 begin at operation 510 with receiving one or more IC dies and a substrate (such as a device or package substrate). The substrate may have a land side (or backside) of the substrate (for example, with an array of one or more of various interconnect interfaces, such as lands or contacts, e.g., for coupling to a motherboard) and a frontside, opposite the backside. The substrate may have one or more IC dies coupled to a frontside of the substrate.

Returning to FIG. 5, methods 500 continue at operation 520 with coupling the received IC die to the backside of the substrate. The IC die may be coupled by any suitable means. In many embodiments, the IC die is coupled to the substrate between the interconnect interfaces, such that at least one interconnect interface is on either side of the IC die. In many embodiments, the IC die is coupled to the substrate within an array of interconnect interfaces (e.g., to be coupled to a motherboard), and the interconnect interfaces surround the IC die on all sides. In many embodiments, the IC die is coupled by soldering the die to the substrate. Other means may be used. In some embodiments, other land-side components are received and coupled (e.g., by solder) to the substrate backside. In some such embodiments, the other components are coupled to the backside between the backside IC die and one or more of the backside interconnect interfaces. In some embodiments, frontside IC dies are received and coupled (e.g., by solder) to the substrate frontside.

FIG. 6A illustrates device 100 with a backside IC die 111 on backside 198 of substrate 199 (for example, following a coupling operation 520 of methods 500). Frontside dies 112 are frontside 197, opposite backside 198. IHS 192 is coupled to dies 112 by TIM 140. Interconnect interfaces 195 are on backside 198. Die 111 and components 191 are on backside 198, between interconnect interfaces 195, surrounded by and within an array of interconnect interfaces 195.

Returning to FIG. 5, methods 500 continue at operation 530 by placing a TIM on the backside die and at multiple locations on the substrate backside. The TIM may be dispensed by any suitable means, e.g., conventionally. The TIM may be any suitable material(s), e.g., a thermally conductive polymer. The TIM may be placed over an entirety of an exposed surface of the backside die. The TIM may be placed at locations on the backside die that a thermally conductive layer is to be coupled to the substrate. In some embodiments, the thermally conductive layer is to be coupled to the substrate to either side of the backside IC die, and TIM is placed at locations to either side of the backside IC die. In some embodiments, the thermally conductive layer is to be coupled to the substrate at an interface encircling or surrounding the backside IC die, and TIM is placed at locations (e.g., many locations) encircling or surrounding the backside IC die. In some embodiments, the TIM is placed in a continuous loop (e.g., a rectangular circuit) encircling or surrounding the backside IC die.

FIG. 6B illustrates device 100 with TIM 140 backside IC die 111 and on backside 198 (for example, following a placing operation 530 of methods 500). TIM 140 is on backside 198 between die 111 and interconnect interfaces 195, on at least two sides of die 111 (and components 191). In some embodiments, TIM 140 is all around die 111 on backside 198. In some embodiments, components 191 are between die 111 and interconnect interfaces 195.

Returning to FIG. 5, methods 500 continue at operation 540 with coupling a thermally conductive layer to the backside IC die and the backside of the substrate at the multiple locations TIM was placed. The thermally conductive layer is coupled over the backside IC die such that the backside IC die is between the thermally conductive layer and the substrate. The thermally conductive layer is a layer that includes a thermally conductive material, such as copper, diamond, graphite, etc. In some embodiments, the thermally conductive layer is coupled to the substrate between at least interconnect interfaces to opposite sides. In some embodiments, an insulating or mask layer is coupled to the substrate, e.g., as an integrated structure with at least the thermally conductive layer. In some embodiments, an interface layer is coupled to the substrate, e.g., as an integrated structure with at least the thermally conductive layer.

FIG. 6C illustrates device 100 with thermally conductive layer 120 over backside IC die 111 and on backside 198 (for example, following a coupling operation 540 of methods 500). In some embodiments, device 100 includes mask layer 130. In some embodiments, mask layer 130 includes openings 230 in and through mask layer 130.

Returning to FIG. 5, methods 500 continue at operation 550 by placing a group of solder bumps at multiple interconnect interfaces on the backside of the substrate. The solder bumps may be placed by any, e.g., conventional, means. In many embodiments, solder is placed over an entire array of interconnect interfaces, surrounding backside IC die, e.g., to be coupled to another substrate (such as a motherboard).

FIG. 6D illustrates device 100 with solder bumps 190 on interconnect interfaces 195 on backside 198 (for example, following a placing operation 550 of methods 500). In some embodiments, device 100 includes mask layer 130 having openings 230 over core layer 120.

Returning to FIG. 5, methods 500 continue at optional operation 560 with placing a second group of second solder bumps on the thermally conductive layer, such that the thermally conductive layer is between the substrate and the second group of second solder bumps. In some embodiments, the second group of second solder bumps are placed on the thermally conductive layer in openings in a mask layer over the thermally conductive layer. The second group of second solder bumps are placed on the thermally conductive layer, which is between the mask layer and the substrate and between the mask layer and the backside IC die.

FIG. 6E illustrates device 100 with solder bumps 290 on thermally conductive layer 120 (in openings in mask layer 130) on backside 198 (for example, following a placing operation 560 of methods 500).

Returning to FIG. 5, methods 500 continue at operation 570 with coupling the first (e.g., device or package) substrate to a second substrate, such as a motherboard (or other printed circuit board (PCB). For example, in many embodiments, the first and second substrates are coupled by solder. Other means may be used. In some embodiments, the backside of the first substrate is coupled to the second substrate by the group of solder bumps at the interconnect interfaces on the backside. In some embodiments, the second substrate includes one or more (e.g., thermal) vias through the second substrate, for example, between the interconnect interfaces. In some such embodiments, the thermally conductive layer is coupled to the second substrate at the plurality of vias by the second solder bumps. In some such embodiments, the thermally conductive layer is coupled to a heat spreader or heat sink by the vias through the second substrate. In this way, heat may be dissipated from the backside IC die by the thermally conductive layer to the second substrate (and vias) and to a heat spreader or heat sink. TIM may be used, for example, to couple the heat spreader or heat sink to the second substrate and vias. The vias may be much as those described at least at FIG. 2 (e.g., vias 281).

FIG. 6F illustrates device 100 with substrate 199 and thermally conductive layer 120 (over IC die 111 and on backside 198) coupled to substrate 189, e.g., at interconnect interfaces 185, 195, 285 (for example, following a coupling operation 570 of methods 500). In some embodiments, thermally conductive layer 120 is coupled to a heat sink or heat spreader (not shown) through bumps 290, interconnect interfaces 285, vias 281, TIM 140, etc. (much as described at least at FIG. 2).

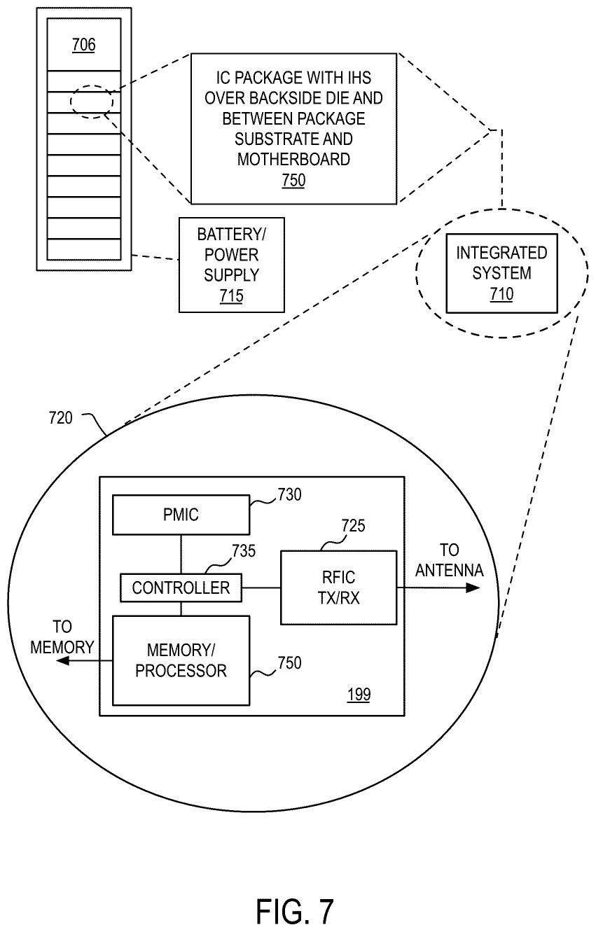

FIG. 7 illustrates a diagram of an example data server machine 706 employing an IC device having an IHS between a package substrate and motherboard and over a backside die, in accordance with some embodiments. Server machine 706 may be any commercial server, for example, including any number of high-performance computing platforms disposed within a rack and networked together for electronic data processing, which in the exemplary embodiment includes one or more devices 750 having a backside IHS between a package substrate and motherboard.

Also as shown, server machine 706 includes a battery and/or power supply 715 to provide power to devices 750, and to provide, in some embodiments, power delivery functions such as power regulation. Devices 750 may be deployed as part of a package-level integrated system 710. Integrated system 710 is further illustrated in the expanded view 720. In the exemplary embodiment, devices 750 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 750 is a microprocessor including a static RAM (SRAM) cache memory. As shown, device 750 may be an IC device having an IHS over a backside die and between a package substrate and motherboard, as discussed herein. Device 750 may be further coupled to (e.g., communicatively coupled to) a board, an interposer, or a substrate 199 along with, one or more of a power management IC (PMIC) 730, RF (wireless) IC (RFIC) 725 including a wideband RF (wireless) transmitter and/or receiver (TX/RX) (e.g., including a digital baseband and an analog front end module further includes a power amplifier on a transmit path and a low noise amplifier on a receive path), and a controller 735 thereof. In some embodiments, RFIC 725, PMIC 730, controller 735, and device 750 include a backside IHS.

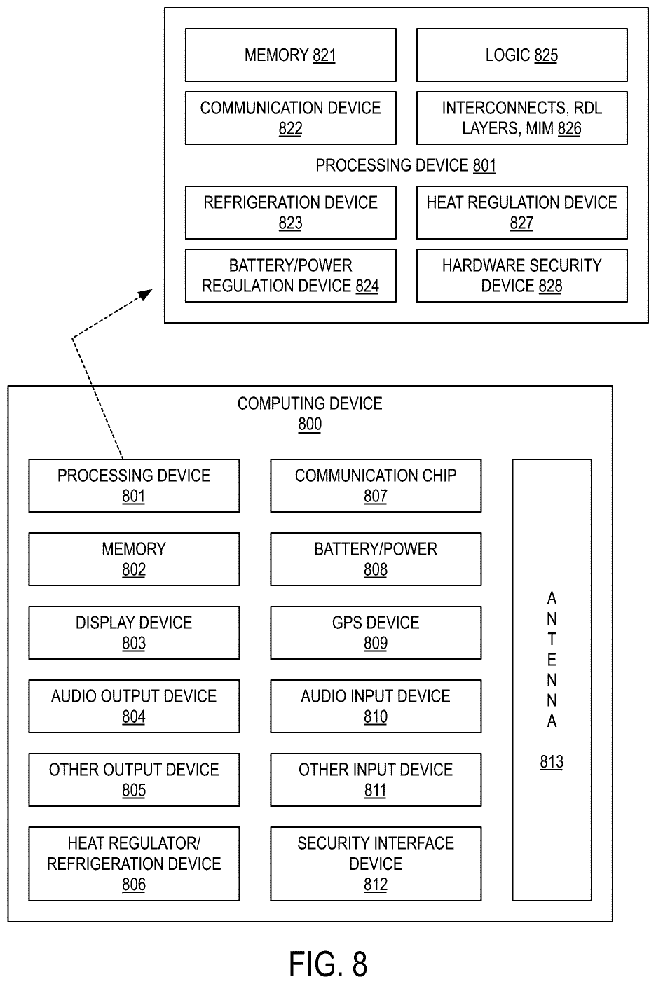

FIG. 8 is a block diagram of an example computing device 800, in accordance with some embodiments. For example, one or more components of computing device 800 may include any of the devices or structures discussed herein. A number of components are illustrated in FIG. 8 as being included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled. In another set of examples, computing device 800 may not include an audio output device 804, other output device 805, global positioning system (GPS) device 809, audio input device 810, or other input device 811, but may include audio output device interface circuitry, other output device interface circuitry, GPS device interface circuitry, audio input device interface circuitry, audio input device interface circuitry, to which audio output device 804, other output device 805, GPS device 809, audio input device 810, or other input device 811 may be coupled.

Computing device 800 may include a processing device 801 (e.g., one or more processing devices). As used herein, the term “processing device” or “processor” indicates a device that processes electronic data from registers and/or memory to transform that electronic data into other electronic data that may be stored in registers and/or memory. Processing device 801 may include a memory 821, a communication device 822, a refrigeration device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 800 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 802 includes memory that shares a die with processing device 801. This memory may be used as cache memory and may include embedded dynamic random-access memory (eDRAM) or spin transfer torque magnetic random-access memory (STT-MRAM).

Computing device 800 may include a heat regulation/refrigeration device 806. Heat regulation/refrigeration device 806 may maintain processing device 801 (and/or other components of computing device 800) at a predetermined low temperature during operation.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a GPS device 809 (or corresponding interface circuitry, as discussed above). GPS device 809 may be in communication with a satellite-based system and may receive a location of computing device 800, as known in the art.

Computing device 800 may include other output device 805 (or corresponding interface circuitry, as discussed above). Examples of the other output device 805 may include an audio codec, a video codec, a printer, a wired or wireless transmitter for providing information to other devices, or an additional storage device.

Computing device 800 may include other input device 811 (or corresponding interface circuitry, as discussed above). Examples of the other input device 811 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, access list management, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-8. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a substrate including a first side and a plurality of interconnect interfaces on the first side, a first integrated circuit (IC) die coupled to the substrate on the first side, between first and second ones of the interconnect interfaces, and a second IC die coupled to the substrate on a second side opposite the first side, and a layer coupled by a thermal interface material to the substrate and the first IC die, wherein the first IC die is between the layer and the substrate, the layer includes a thermally conductive material, and the layer is coupled to the first side between the first IC die and the first one of the interconnect interfaces and between the first IC die and the second one of the interconnect interfaces.

In one or more second embodiments, further to the first embodiments, the substrate is a first substrate, and the plurality of interconnect interfaces is a plurality of first interconnect interfaces, also including a second substrate coupled to the first substrate, the second substrate including a plurality of second interconnect interfaces coupled to the plurality of first interconnect interfaces, wherein the layer and the first IC die are between the first and second substrates and between third and fourth ones of the second interconnect interfaces.

In one or more third embodiments, further to the first or second embodiments, the first and second interconnect interfaces are coupled by a first plurality of first solder regions, and the layer and the second substrate are coupled by a second plurality of second solder regions.

In one or more fourth embodiments, further to the first through third embodiments, the thermal interface material is a first thermal interface material, the second substrate includes a plurality of vias through the second substrate and coupled by a second thermal interface material to a metallization structure on a third side of the second substrate opposite the first substrate, the plurality of vias are coupled to the layer by second solder regions, and the vias include a second thermally conductive material.

In one or more fifth embodiments, further to the first through fourth embodiments, the layer includes a first end and a second end opposite the first end, the layer is coupled to the substrate at the first and second ends, and the first IC die is coupled to the substrate between the first and second ends.

In one or more sixth embodiments, further to the first through fifth embodiments, the layer is coupled to the substrate at an interface, the interface encircles the first IC die on the first side, and the layer and the substrate enclose the first IC die.

In one or more seventh embodiments, further to the first through sixth embodiments, the layer of the thermally conductive material is a first layer, also including a second layer, wherein the first layer is between the second layer and the substrate, and the second layer covers a region of the first layer.

In one or more eighth embodiments, further to the first through seventh embodiments, the second layer includes a plurality of openings through the second layer, the first layer includes a plurality of sectors not covered by the second layer, individual ones of the sectors are encircled by the region of the first layer, and individual ones of the sectors are adjacent to corresponding ones of the plurality of openings.

In one or more ninth embodiments, further to the first through eighth embodiments, the apparatus also includes first and second pluralities of solder bumps, wherein the first plurality of solder bumps is on the plurality of interconnect interfaces, and the second plurality of solder bumps is in the sectors of the first layer and the plurality of openings through the second layer.

In one or more tenth embodiments, further to the first through ninth embodiments, the layer of the thermally conductive material is a first layer, also including a third layer and first and second pluralities of solder bumps, wherein the first layer is between the third layer and the substrate, the first plurality of solder bumps is on the plurality of interconnect interfaces, and the second plurality of solder bumps is on the third layer.

In one or more eleventh embodiments, further to the first through tenth embodiments, the apparatus also includes a second layer, wherein the third layer is between the first and second layers, the second layer covers a region of the third layer, the second layer includes a plurality of openings through the second layer, and the second plurality of solder bumps are located at the plurality of openings through the second layer.

In one or more twelfth embodiments, further to the first through eleventh embodiments, the layer of the thermally conductive material is a layer of copper, a layer of graphite, or a layer of a composite including diamond.

In one or more thirteenth embodiments, an apparatus includes first and second substrates coupled by a plurality of first interconnect interfaces on the first substrate and a plurality of second interconnect interfaces on the second substrate, first and second integrated circuit (IC) dies coupled to the second substrate, wherein the second substrate is between the first and second IC dies, and the first IC die is between the first and second substrates and surrounded by the second interconnect interfaces, and a layer including a thermally conductive material, the layer coupled to the second substrate between the first and second substrates and between the first IC die and the second interconnect interfaces, wherein the first IC die is between the layer and the second substrate.

In one or more fourteenth embodiments, further to the thirteenth embodiments, the layer includes a first end and a second end opposite the first end, the layer is coupled to the second substrate at the first and second ends, the layer is coupled to the second substrate by a thermal interface material, the layer is coupled to the first IC die by the thermal interface material, and the first IC die is coupled to the second substrate between the first and second ends.

In one or more fifteenth embodiments, further to the thirteenth or fourteenth embodiments, the first substrate includes a plurality of vias through the first substrate, the first and second substrates are coupled at the first and second interconnect interfaces by a first plurality of first solder regions, and the layer and the first substrate are coupled at the vias by a second plurality of second solder regions.

In one or more sixteenth embodiments, further to the thirteenth through fifteenth embodiments, the layer is a first layer, also including a second layer between the first layer and the first substrate, wherein the second layer includes a plurality of openings through the second layer, and the second solder regions are in corresponding openings through the second layer and between the first layer and the first substrate.

In one or more seventeenth embodiments, further to the thirteenth through sixteenth embodiments, the apparatus also includes a power supply coupled to the first substrate.

In one or more eighteenth embodiments, a method includes coupling a first integrated circuit (IC) die to a first side of a substrate, the first side including a plurality of interconnect interfaces, wherein the first IC die is coupled to the substrate between at least first and second ones of the interconnect interfaces, and one or more second IC dies are coupled to a second side of the substrate opposite the first side, placing a thermal interface material at a first location on the first IC die and at a plurality of second locations on the first side of the substrate, coupling a first layer to the first IC die and the first side of the substrate at the first and second locations, wherein the first layer includes a thermally conductive material and is coupled to the substrate between at least the first and second ones of the interconnect interfaces, and the first IC die is between the first layer and the substrate, and placing a plurality of first solder bumps at the plurality of interconnect interfaces on the first side of the substrate.

In one or more nineteenth embodiments, further to the eighteenth or nineteenth embodiments, the method also includes placing a plurality of second solder bumps on exposed sectors of the first layer, wherein the first layer is between the substrate and the second solder bumps, the first layer is between the substrate and a second layer, the first layer is between the first IC die and the second layer, the second layer covers a region of the first layer, the region of the first layer surrounds the exposed sectors of the first layer, and the exposed sectors of the first layer are not covered by the second layer.

In one or more twentieth embodiments, further to the eighteenth or nineteenth embodiments, the substrate is a first substrate, also including coupling the first substrate to a second substrate, wherein the second substrate includes a plurality of vias through the second substrate, the first side of the first substrate is coupled to the second substrate by the first solder bumps at the plurality of interconnect interfaces, and the first layer is coupled to the second substrate by the second solder bumps at the plurality of vias through the second substrate.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a substrate comprising a first side and a plurality of interconnect interfaces on the first side;
a first integrated circuit (IC) die coupled to the substrate on the first side, between first and second ones of the interconnect interfaces, and a second IC die coupled to the substrate on a second side opposite the first side; and
a layer coupled by a thermal interface material to the substrate and the first IC die, wherein the first IC die is between the layer and the substrate, the layer comprises a thermally conductive material, and the layer is coupled to the first side between the first IC die and the first one of the interconnect interfaces and between the first IC die and the second one of the interconnect interfaces.

2. The apparatus of claim 1, wherein the substrate is a first substrate, and the plurality of interconnect interfaces is a plurality of first interconnect interfaces, further comprising a second substrate coupled to the first substrate, the second substrate comprising a plurality of second interconnect interfaces coupled to the plurality of first interconnect interfaces, wherein the layer and the first IC die are between the first and second substrates and between third and fourth ones of the second interconnect interfaces.

3. The apparatus of claim 2, wherein the first and second interconnect interfaces are coupled by a first plurality of first solder regions, and the layer and the second substrate are coupled by a second plurality of second solder regions.

4. The apparatus of claim 3, wherein the thermal interface material is a first thermal interface material, the second substrate comprises a plurality of vias through the second substrate and coupled by a second thermal interface material to a metallization structure on a third side of the second substrate opposite the first substrate, the plurality of vias are coupled to the layer by second solder regions, and the vias comprise a second thermally conductive material.

5. The apparatus of claim 1, wherein the layer comprises a first end and a second end opposite the first end, the layer is coupled to the substrate at the first and second ends, and the first IC die is coupled to the substrate between the first and second ends.

6. The apparatus of claim 5, wherein the layer is coupled to the substrate at an interface, the interface encircles the first IC die on the first side, and the layer and the substrate enclose the first IC die.

7. The apparatus of claim 1, wherein the layer of the thermally conductive material is a first layer, further comprising a second layer, wherein the first layer is between the second layer and the substrate, and the second layer covers a region of the first layer.

8. The apparatus of claim 7, wherein the second layer comprises a plurality of openings through the second layer, the first layer comprises a plurality of sectors not covered by the second layer, individual ones of the sectors are encircled by the region of the first layer, and the individual ones of the sectors are adjacent to corresponding ones of the plurality of openings.

9. The apparatus of claim 8, further comprising first and second pluralities of solder bumps, wherein the first plurality of solder bumps is on the plurality of interconnect interfaces, and the second plurality of solder bumps is in the sectors of the first layer and the plurality of openings through the second layer.

10. The apparatus of claim 1, wherein the layer of the thermally conductive material is a first layer, further comprising a third layer and first and second pluralities of solder bumps, wherein the first layer is between the third layer and the substrate, the first plurality of solder bumps is on the plurality of interconnect interfaces, and the second plurality of solder bumps is on the third layer.

11. The apparatus of claim 10, further comprising a second layer, wherein the third layer is between the first and second layers, the second layer covers a region of the third layer, the second layer comprises a plurality of openings through the second layer, and the second plurality of solder bumps are located at the plurality of openings through the second layer.

12. The apparatus of claim 1, wherein the layer of the thermally conductive material is a layer of copper, a layer of graphite, or a layer of a composite comprising diamond.

13. An apparatus, comprising:
first and second substrates coupled by a plurality of first interconnect interfaces on the first substrate and a plurality of second interconnect interfaces on the second substrate;
first and second integrated circuit (IC) dies coupled to the second substrate, wherein the second substrate is between the first and second IC dies, and the first IC die is between the first and second substrates and surrounded by the second interconnect interfaces; and
a layer comprising a thermally conductive material, the layer coupled to the second substrate between the first and second substrates and between the first IC die and the second interconnect interfaces, wherein the first IC die is between the layer and the second substrate.

14. The apparatus of claim 13, wherein the layer comprises a first end and a second end opposite the first end, the layer is coupled to the second substrate at the first and second ends, the layer is coupled to the second substrate by a thermal interface material, the layer is coupled to the first IC die by the thermal interface material, and the first IC die is coupled to the second substrate between the first and second ends.

15. The apparatus of claim 14, wherein the first substrate comprises a plurality of vias through the first substrate, the first and second substrates are coupled at the first and second interconnect interfaces by a first plurality of first solder regions, and the layer and the first substrate are coupled at the vias by a second plurality of second solder regions.

16. The apparatus of claim 15, wherein the layer is a first layer, further comprising a second layer between the first layer and the first substrate, wherein the second layer comprises a plurality of openings through the second layer, and the second solder regions are in corresponding openings through the second layer and between the first layer and the first substrate.

17. The apparatus of claim 16, further comprising a power supply coupled to the first substrate.

18. A method, comprising:
coupling a first integrated circuit (IC) die to a first side of a substrate, the first side comprising a plurality of interconnect interfaces, wherein the first IC die is coupled to the substrate between at least first and second ones of the interconnect interfaces, and one or more second IC dies are coupled to a second side of the substrate opposite the first side;
placing a thermal interface material at a first location on the first IC die and at a plurality of second locations on the first side of the substrate;
coupling a first layer to the first IC die and the first side of the substrate at the first and second locations, wherein the first layer comprises a thermally conductive material and is coupled to the substrate between at least the first and second ones of the interconnect interfaces, and the first IC die is between the first layer and the substrate; and
placing a plurality of first solder bumps at the plurality of interconnect interfaces on the first side of the substrate.

19. The method of claim 18, further comprising placing a plurality of second solder bumps on exposed sectors of the first layer, wherein:
the first layer is between the substrate and the second solder bumps;
the first layer is between the substrate and a second layer;
the first layer is between the first IC die and the second layer;
the second layer covers a region of the first layer;
the region of the first layer surrounds the exposed sectors of the first layer; and
the exposed sectors of the first layer are not covered by the second layer.

20. The method of claim 19, wherein the substrate is a first substrate, further comprising coupling the first substrate to a second substrate, wherein the second substrate comprises a plurality of vias through the second substrate, the first side of the first substrate is coupled to the second substrate by the first solder bumps at the plurality of interconnect interfaces, and the first layer is coupled to the second substrate by the second solder bumps at the plurality of vias through the second substrate.
